(19) United States
(12) Patent Application Publication
(10) Pub. No.: US 2025/0347740 A1
(43) Pub. Date: Nov. 13, 2025

(54) ELECTRICAL CONNECTING APPARATUS

(71) Applicants: KABUSHIKI KAISHA NIHON MICRONICS, Tokyo (JP); TANAKA PRECIOUS METAL TECHNOLOGIES Co., Ltd., Tokyo (JP)

(72) Inventors: Toshinori OMORI, Tokyo (JP); Takayuki NARUMI, Tokyo (JP); Kazuya GOTO, Tokyo (JP); Fuga SHIMOYAMA, Tokyo (JP); Toshiyuki KUDO, Tokyo (JP); Takeshi KONDO, Kanagawa (JP)

(21) Appl. No.: 19/189,904

(22) Filed: Apr. 25, 2025

(30) Foreign Application Priority Data
May 9, 2024 (JP) 2024-076753

(51) Int. Cl. G01R 31/28; G01R 1/073

(52) U.S. Cl. CPC G01R 31/2889; G01R 1/07342

(57) ABSTRACT

To provide an electrical connecting apparatus capable of improving adhesion between ceramics and metal and of bonding strongly therebetween, even under high-temperature environments. The present disclosure provides an electrical connecting apparatus configured to electrically contact a probe with each of a plurality of electrode terminals of a device under test to electrically connect a test apparatus and the device under test, the electrical connecting apparatus including: a wiring substrate electrically connected to the test apparatus; a probe substrate including the plurality of probes; and a connection unit configured to electrically connect the wiring substrate to each of the plurality of probes of the probe substrate, wherein an annular flange for connecting the probe substrate to the connection unit is bonded to an edge portion of the probe substrate with a bonding material without using a fixing tool.

### CROSS-REFERENCE TO RELATED APPLICATIONS

The present application claims priority under 35 U.S.C. § 119 to Japanese Patent Application No. 2024-076753, filed on May 9, 2024. The contents of this application are incorporated herein by reference in their entirety.

### TECHNICAL FIELD

The present disclosure can be applied to an electrical connecting apparatus used for electrical tests, such as a current-carrying test, of a semiconductor integrated circuit formed on a semiconductor wafer, for example.

### BACKGROUND ART

For example, a plurality of semiconductor integrated circuits is formed on a semiconductor wafer, and an electrical test of each semiconductor integrated circuit is required to verify whether the electrical characteristics of each semiconductor integrated circuit are as specified.

In an electrical test, a probe card having a plurality of probes is attached to a test head of a test apparatus (tester), and tips of the probes are electrically contacted to respective corresponding to electrode terminals of the semiconductor integrated circuit. Moreover, the test apparatus supplies a test signal to the electrode terminal of the semiconductor integrated circuit through the probe, and the semiconductor integrated circuit outputs an electrical signal in response to the test signal and the electrical signal is provided to the test apparatus through the probe. In this manner, the test apparatus can test whether the electrical characteristics of the semiconductor integrated circuit are as specified on the basis of the electrical signal received from the semiconductor integrated circuit in response to the test signal.

For example, Patent Literature 1 discloses a method of assembling a probe card. The method of assembling the probe card will now be briefly described with reference to Patent Literature 1. Conventionally, in order to fix a support member of a probe substrate, a general-purpose adhesive is applied to an edge portion of a ceramic substrate and a ring flange is attached thereto. After that, the ring flange is left until the general-purpose adhesive dries and hardens to be fixed, and then a bolt is screwed into a female threaded hole of the attached ring flange, and subsequently a spacer is disposed between the ring flange and a lower surface of a wiring substrate so as to be held.

### CITATION LIST

### Patent Literature

Patent Literature 1: International Publication No. WO 2006/126279

### SUMMARY OF INVENTION

### Technical Problem

By the way, depending on the application of the semiconductor integrated circuit, it may be used under a high-temperature environment, e.g., 150° C. or higher, and therefore the probe card is also required to have durability in the high-temperature environment.

However, general-purpose adhesives have no sufficient durability under high-temperature environments, and the adhesive may break or a bonded surface between the support member and the probe substrate may peel off.

Moreover, when the general-purpose adhesive is applied to an edge portion of the ceramic substrate and is bonded to the ring flange under a high-temperature environment, cracks may occur in the ceramic due to a difference between a linear expansion coefficient of the ceramic and that of the ring flange material.

Although the case of fixing a ceramic probe substrate has been described as an example, the same problem exists in other electronic members for bonding one component member to another component member of an electrical connecting apparatus, represented by a probe card.

Accordingly, in view of the above-described problems, the present disclosure aims to provide an electrical connecting apparatus capable of improving adhesion between ceramics and metal and of bonding strongly therebetween, even under high-temperature environments.

### Solution to Problem

In order to solve such a problem, the present disclosure provides an electrical connecting apparatus configured to electrically contact a probe with each of a plurality of electrode terminals of a device under test to electrically connect a test apparatus to the device under test, the electrical connecting apparatus including: (1) a wiring substrate electrically connected to the test apparatus; (2) a probe substrate including the plurality of probes; and (3) a connection unit configured to electrically connect the wiring substrate to each of the plurality of probes of the probe substrate, wherein an annular flange for connecting the probe substrate to the connection unit is bonded to an edge portion of the probe substrate with a bonding material without using a fixing tool.

### Advantageous Effects of Invention

According to the present disclosure, it is possible to improve the adhesion between the ceramics and the metal and to bond strongly therebetween, even under high-temperature environments.

### BRIEF DESCRIPTION OF DRAWINGS

FIG. 1 is a configuration diagram illustrating a configuration of an electrical connecting apparatus according to an embodiment.

FIG. 2 is a flow chart illustrating a method of assembling a probe substrate according to the embodiment.

FIG. 3A is a front view diagram and a side view diagram of a probe substrate before a ring flange is attached, and FIG. 3B is a front view diagram and a side view diagram of the probe substrate after the ring flange is attached.

FIG. 4 is a front view diagram and a side view diagram of a probe substrate after a conventional ring flange is attached.

FIG. 5 is a diagram illustrating characteristics of an example of a bonding material according to the embodiment.

FIG. 6 is a diagram illustrating a cycle test result when bonding materials according to the embodiment are used (part 1).

FIG. 7 is a diagram illustrating a cycle test result when the bonding materials according to the embodiment are used (part 2).

FIG. 8 is an explanatory diagram for explaining a cycle test.

FIG. 9 is a diagram illustrating a cycle test result when a cure temperature, cure time, and post-cure film thickness are changed using the bonding material #1 as a bonding material according to the embodiment (part 1).

FIG. 10 is a diagram illustrating a cycle test result when a cure temperature, cure time, and post-cure film thickness are changed using the bonding material #1 as a bonding material according to the embodiment (part 2).

FIG. 11 is a diagram illustrating a ring flange according to a modified embodiment (part 1).

FIG. 12 is a diagram illustrating a ring flange according to a modified embodiment (part 2).

FIG. 13 is a diagram illustrating a ring flange according to a modified embodiment (part 3).

### DESCRIPTION OF EMBODIMENTS

### (A) Principal Embodiment

Hereinafter, embodiments of an electrical connecting apparatus according to the present disclosure will be described in detail with reference to the drawings.

The present embodiment illustrates a case where an electrical connecting apparatus according to the present disclosure is applied to a probe card configured to electrically contact a probe (electrical contactor) with each of a plurality of electrode terminals of a device under test and to electrically connect a test apparatus to the device under test.

There are two types of probe cards: a probe card with a PCB in which the PCB is fixed to an outer peripheral end of a multilayer wiring substrate (probe substrate) and is attached to a tester (test apparatus); and a probe card without a PCB in which a multilayer wiring substrate (probe substrate) is attached to the tester (test apparatus) without using the PCB. In the present embodiment, a case where the electrical connecting apparatus according to the present disclosure is applied to a probe card without a PCB will be illustrated.

### (A-1) Electrical Connecting Apparatus

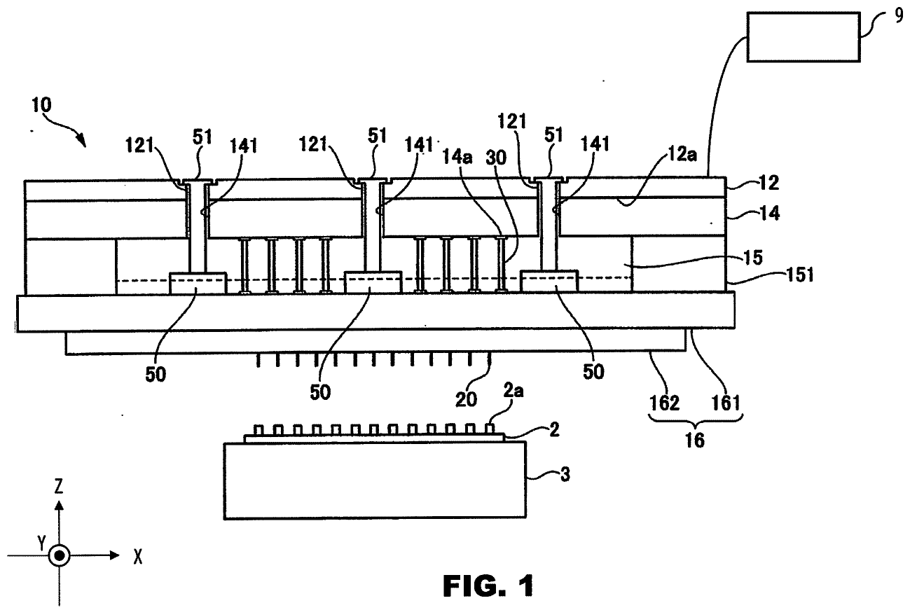

FIG. 1 is a configuration diagram illustrating a configuration of an electrical connecting apparatus according to the embodiment.

In the description of the following drawings to be explained, the identical or corresponding reference sign is attached to the identical or corresponding part. However, it should be noted that the drawings are schematic, and the dimensions and the thickness, etc. of each component differ from an actual thing. Moreover, the dimensions and proportions of corresponding components differ between the drawings. The embodiments described hereinafter merely exemplify the device and method for materializing the technical idea; and the embodiments do not limit the material, shape, structure, arrangement, etc. of each component disclosed herein. Moreover, each drawing illustrates the main component members, but the present disclosure is not limited to the illustrated members and actually also include members that are not illustrated.

In FIG. 1, an electrical connecting apparatus 10 according to the present embodiment includes: a plate-shaped support member 12; a plate-shaped wiring substrate 14 held on a second surface (e.g., lower surface) 12a of the support member 12; an electrical connecting unit 15 electrically connected to the wiring substrate 14; and a probe substrate 16 electrically connected to the electrical connecting unit 15 and having a plurality of electrical contactors (hereinafter also referred to as “probes”) 20.

The electrical connecting apparatus 10 is configured to electrically connect between an electrode terminal 2a of a device under test 2, and a tester (test apparatus) 9 side, and is also referred to as a probe card. A large number of fixation members (e.g., screwing members, such as bolts) are used to assemble the support member 12, the wiring substrate 14, the electrical connecting unit 15, and the probe substrate 16, into the electrical connecting apparatus 10, but such fixation members are not illustrated in FIG. 1.

The electrical connecting apparatus 10 is used to be attached to a test head of the tester (test apparatus) 9 when an electrical test of the semiconductor integrated circuit (device under test) 2 formed on a semiconductor wafer is performed.

During testing, the electrical connecting apparatus 10 presses the device under test 2 toward the probe substrate 16 to electrically contact a tip portion of each probe 20 on the probe substrate 16 with each electrode terminal 2a of the device under test 2. Then, the tester 9 supplies an electrical signal for testing to the electrode terminal 2a of the device under test 2, the device under test 2 outputs an electrical signal on the basis of the supplied electrical signal, and the electrical signal from the device under test 2 is provided to the tester 9. In this way, the tester 9 acquires the electrical signal from the device under test 2 in response to the electrical signal for testing output to the device under test 2, thereby the tester 9 conducts an electrical test of the device under test 2.

The device under test 2 may be a semiconductor integrated circuit formed on a semiconductor wafer. As illustrated in FIG. 1, the semiconductor wafer placed on an upper surface of a wafer chuck 3 is held on the wafer chuck 3 through vacuum adsorption. During testing, the wafer chuck 3 moves, for example, driven by a test stage which is a multi-axis stage, the semiconductor wafer approaches a lower surface of the electrical connecting apparatus 10, and a position of the device under test 2 is adjusted so that the electrode terminals 2a of the device under test 2 are respectively in contact with tips of the probes 20.

[Support Member]

The support member 12 supports the wiring substrate 14 in order to suppress deformation (e.g., bending or the like) of the wiring substrate 14. For example, since the probe substrate 16 has a large number of probes 20, a weight of the probe substrate 16 attached to the wiring probe substrate 14 side is large, and it is necessary to maintain horizontality of the wiring substrate 14 in order to ensure contact with the electrode terminals 2a of the device under test 2.

During testing, the probe substrate 16 is pressed by the device under test 2 on the wafer chuck 3, so that the tip portions of the probes 20 protruding to a second surface (e.g., lower surface) side of the probe substrate 16 are in contact with the electrode terminals 2a of the device under test 2. At this time, a reaction force (contact load) is applied to push up from bottom to top (from the device under test 2 side towards the probe substrate 16 side), and a large load is also applied to the wiring substrate 14. Thus, in order to suppress deformation (e.g., bending etc.) of the wiring substrate 14, to which a large load is applied, the support member 12 functions as a deformation prevention member.

A plurality of through-holes 121 passing through the first surface (e.g., upper surface) and the second surface (e.g., lower surface) are formed in the support member 12. Each through-hole 121 is provided at a position corresponding to a position of each anchor 50 disposed on the first surface (e.g., upper surface) of the probe substrate 16 described later, which is a position corresponding to a position of each through-hole 141 provided in the wiring substrate 14.

A spacer (hereinafter, also referred to as a “supporter”) 51 is inserted into each through-hole 121 of the support member 12 downward from above the support member 12 (from the first surface side towards the second surface side), and is configured such that a lower end portion of the spacer 51 can be fixed to the corresponding anchor 50.

For example, the lower end portion of the spacer 51 is a male screw portion, and a substantially central portion of the anchor 50 disposed on the first surface (e.g., upper surface) of the probe substrate 16 is a female screw portion. The fixing can be achieved by screwing the lower end portion (male screw portion) of the spacer 51 into the female screw portion of the anchor 50. Consequently, a distance between the first surface (e.g., upper surface) of the probe substrate 16 and the first surface (e.g., upper surface) of the support member 12 can be maintained at a predetermined distance length. [Wiring Substrate]

The wiring substrate 14 is, for example, a substantially plate-shaped printed board or the like formed with a resin material such as polyimide, for example. A large number of electrode terminals (not illustrated) to be electrically connected to a test head of a tester 9 are disposed in a peripheral edge of a first surface (e.g., upper surface) of the wiring substrate 14.

Moreover, a wiring pattern is formed on the second surface (e.g., lower surface) of the wiring substrate 14, and a connecting terminal 14a of the wiring pattern is electrically connected to an upper end portion of the connector 30, such as a pogo pin, provided in the electrical connecting unit 15.

Furthermore, a wiring circuit (not illustrated) is formed inside the wiring substrate 14, and the wiring pattern formed on the lower surface of the wiring substrate 14 and the electrode terminal formed on the upper surface of the wiring substrate 14 can be connected to each other through the wiring circuit formed inside the wiring substrate 14.

Accordingly, it is possible to conduct an electrical signal through the wiring circuit in the wiring substrate 14 between each connector 30 of the electrical connecting unit 15, which is to be electrically connected to the connecting terminal 14a of the wiring pattern formed on the lower surface of the wiring substrate 14, and the test head, which is to be connected to the electrode terminal formed on the upper surface of the wiring substrate 14. A plurality of electronic parts required for the electrical test conducted on the device under test 2 is also disposed on the upper surface of the wiring substrate 14.

A plurality of through-hole 141 passing through the first surface (e.g., upper surface) and the second surface (e.g., lower surface) of the wiring substrate 14 is formed in the wiring substrate 14. Each through-hole 141 is disposed at a position corresponding to the position of each anchor 50 on the upper surface of the probe substrate 16, which is a position corresponding to the position of each through-hole 121 disposed on the support member 12.

Each through-hole 141 has an opening shape that can be determined in accordance with a shape of the spacer 51 to be inserted thereinto. Moreover, in order to allow each spacer 51 to be inserted into each through-hole 141, an inner diameter of each through-hole 141 is approximately equal to or slightly larger than an outer diameter of each spacer 51.

The present embodiment illustrates a case where the opening shape of the through-hole 141 is a substantially circular shape in order to illustrate a case where the spacer 51 is a circular columnar member, but the opening shape thereof is not limited to this example. For example, the spacer 51 may be a right prism member having a substantially square cross-sectional shape, a polygonal prism member having a polygonal cross-sectional shape, or the like, and even in such cases, the opening shape of the through-hole 141 may be a shape that can be inserted into the spacer 51.

[Electrical Connecting Unit]

The electrical connecting unit 15 includes a plurality of connectors 30, such as pogo pins, for example. In an assembled state of the electrical connecting apparatus 10, an upper end portion of each connector 30 is electrically connected to each connecting terminal 14a of the wiring pattern formed on the lower surface of the wiring substrate 14, and a lower end portion of each connector 30 is connected to each pad provided on the upper surface of the probe substrate 16. Since the tip portion of the probe 20 is in electrically contact with the electrode terminal 2a of the device under test 2, the electrode terminal of the device under test 2 is electrically connected to the tester through the probe 20 and the connector 30.

For example, the electrical connecting unit 15 has a plurality of insertion holes for inserting each of the plurality of connectors 30 thereinto. When the connectors 30 are respectively inserted into the insertion holes, the upper and lower end portions of the connectors 30 protrude. It is to be noted that, in the electrical connecting unit 15, a mechanism of attaching the plurality of connectors 30 is not limited to the configuration of providing the through holes, and various configurations can be widely applied. A flange portion 151 is provided around a periphery of the electrical connecting unit 15.

[Probe Substrate]

The probe substrate 16 is a substrate including a plurality of probes 20 provided thereon and is formed into a substantially circular shape or a polygonal shape (e.g., hexadecagon or the like). The probe 20 exemplified herein is, for example, a cantilever type probe (electrical contactor), but is not limited to such an example. Moreover, the probe substrate 16 includes a substrate member 161, for example, which is a ceramic substrate, and a multilayer wiring substrate 162 formed on a lower surface of the substrate member 161.

A large number of electrical conduction paths (not illustrated) passing through in a plate thickness direction are formed inside the substrate member 161 of the ceramic substrate. Moreover, a connecting terminal of the wiring pattern is formed on a first surface (e.g., upper surface) of the substrate member 161, and one end of an electrical conduction path in the substrate member 161 is connected to the connecting terminal formed on the upper surface of the substrate member 161. On the second surface (e.g., lower surface) of the substrate member 161, the other end of the electrical conduction path in the substrate member 161 is connected to a connecting terminal provided in a first surface (e.g., upper surface) of the multilayer wiring substrate 162.

The multilayer wiring substrate 162 is a plurality of multilayer substrates formed, for example, of a synthetic resin member such as polyimide, and a wiring path (not illustrated) is formed between the plurality of multilayer substrates. One end of the wiring path in the multilayer wiring substrate 162 is connected to the other end of the electrical wiring path on the substrate member 161 side, which is a ceramic substrate, and the other end of the multilayer wiring substrate 162 is connected to a probe land provided on the second surface (e.g., lower surface) of the multilayer wiring substrate 162. The plurality of probes 20 are disposed on the probe land on the second surface (e.g., lower surface) of the multilayer wiring substrate 162, and each probe 20 is respectively electrically connected to the corresponding connecting terminals 14a of the wiring substrate 14 through the electrical connecting unit 15.

### (A-2) Method of Assembling Probe Substrate

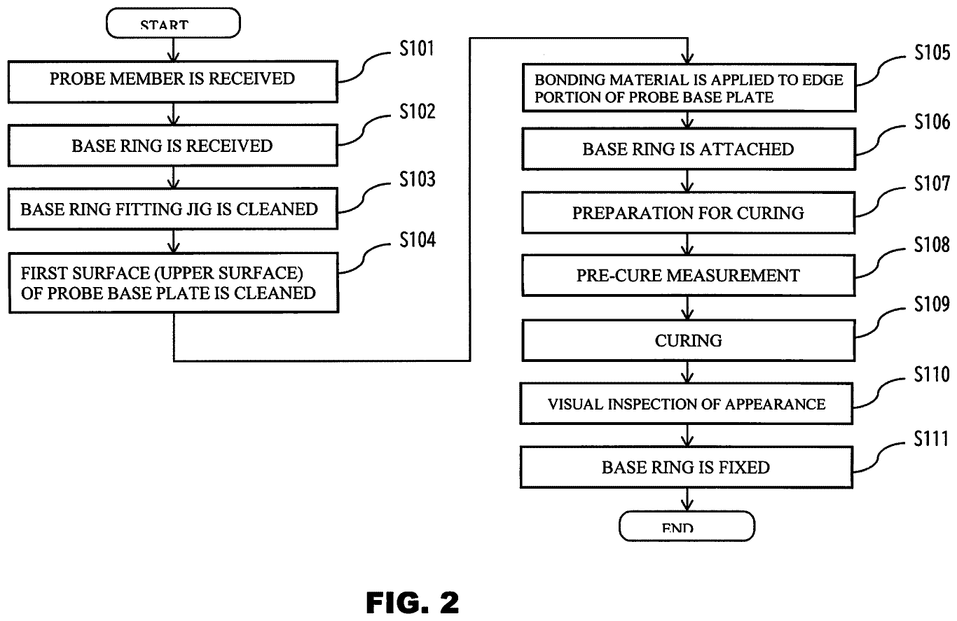

FIG. 2 is a flow chart explaining a method of assembling the probe substrate 16 according to the embodiment.

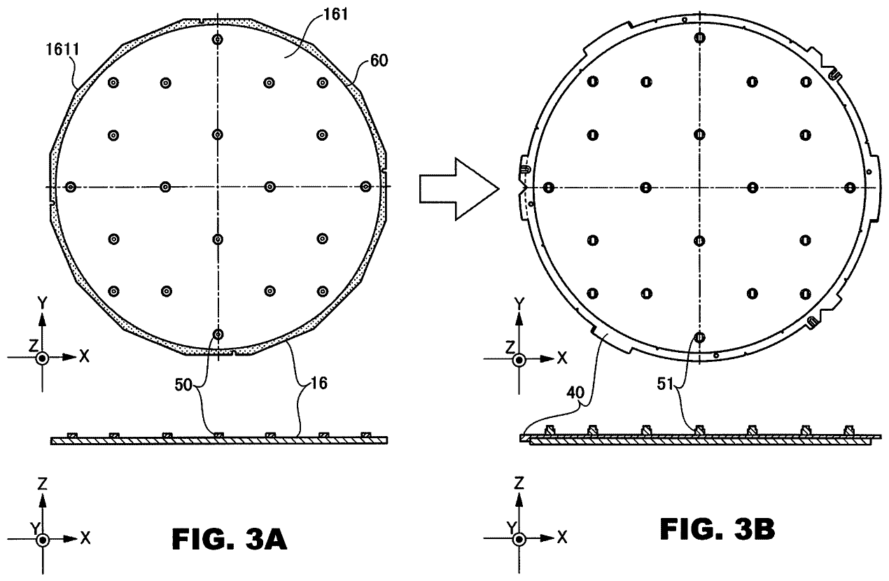

FIG. 3A is a front view diagram and a side view diagram illustrating a configuration of the probe substrate 16 before a ring flange is attached, and FIG. 3B is a front view diagram and a side view diagram of the probe substrate 16 after the ring flange is attached.

When assembling the electrical connecting apparatus 10, a ring flange (also referred to as “annular flange”) 40 is attached to an edge portion of the probe substrate 16, and a probe substrate 16 to which the ring flange 40 is attached is fixed to the electrical connecting unit 15.

Here, the ring flange 40 is an assembly part for attaching the probe substrate 16 to the wiring substrate 14, and is an annular member formed of, for example, stainless steel, which is alloy steel containing iron, chromium, and the like. It is to be noted that the ring flange 40 exemplified herein is, for example, made of stainless steel, but is not limited to such an example. The stainless steel ring flange 40 is bonded to be fixed to an edge portion 1611 of the substrate member 161 of the ceramic substrate by means of a bonding material 60.

Hereinafter, a method of assembling the probe substrate 16 by attaching the ring flange 40 to the substrate member 161 of the ceramic substrate will be described, with reference to FIGS. 2, 3A, and 3B. Assembly can be automated using assembly apparatus. In FIG. 2, first, the substrate member 161, which is a ceramic substrate, is received (Step S101), the ring flange 40 is further received (Step S102), and the substrate member 161 and the ring flange 40 are set.

An attaching jig for attaching the ring flange 40 is cleaned (Step S103). Moreover, the first surface (e.g., upper surface) of the substrate member 161, which is a ceramic substrate, is cleaned (Step S104).

Then, in order to attach the ring flange 40 to the edge portion of the substrate member 161, the bonding material 60 is applied to the edge portion 1611 of the first surface (e.g., upper surface) of the substrate member 161 (Step S105), and the ring flange 40 is attached to the edge portion 1611 of the substrate member 161 (Step S106).

Here, in order to reliably ensure the bonding between the substrate member 161 formed of ceramics and the ring flange 40 formed of stainless steel, a preparation for curing of the bonding material 60 is performed (Step S107).

Moreover, a pre-cure measurement is performed to measure a state of the substrate member 161 and the ring flange 40 before the bonding material 60 is cured (Step S108). Thereafter, in a state where the ring flange 40 is attached to the edge portion 1611 of the substrate member 161, the bonding material 60 is cured by heating (Step S109).

After curing, the state of an appearance of the probe substrate 16 and the ring flange 40 is visually inspected (Step S110), and if there is no problem, the ring flange 40 is fixed (Step S111), and the probe substrate 16 can be assembled.

As illustrated in FIG. 3A, the first surface (e.g., upper surface) of the substrate member 161 of the probe substrate 16 is formed of ceramics, and a plurality of anchors 50 is provided for supporting the spacer 51.

When attaching the ring flange 40 to the edge portion 1611 of the substrate member 161, the bonding material 60 is applied to the entire circumference of an edge portion 1611 on an upper surface of the substrate member 161 of the probe substrate 16 by a width matched with a width length of the ring flange 40. Then, as illustrated in FIG. 3B, the ring flange 40 is attached to an applied surface of the bonding material 60 on the upper surface of the substrate member 161.

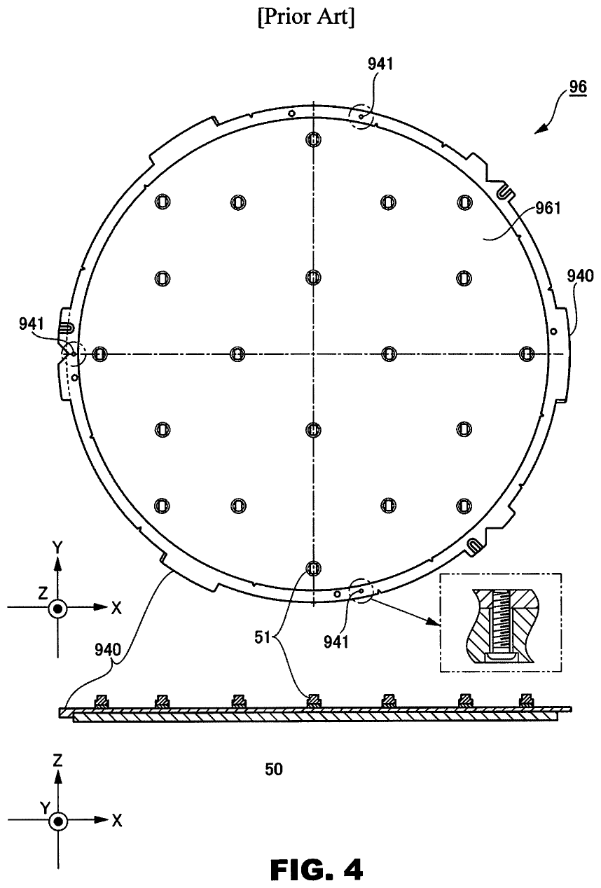

FIG. 4 illustrates a conventional probe substrate 96. FIG. 3B illustrates a probe substrate 16 according to the embodiment.

A difference in structure between the probe substrate 16 of the present embodiment and the conventional probe substrate 96 will now be described, with reference to FIGS. 3B and 4.

In FIG. 3B, a bonding material 60 is used that has a low elastic modulus and high bonding strength even under high temperature environments. Therefore, even in a high temperature environment of, for example, 150° C. or higher, or even when the temperature changes within a range from, for example, a low temperature of −20° C. to a high temperature of 150° C., the bonding material 60 does not peel off, and the substrate member 161 and the ring flange 40 can be maintained in a bonded state.

In contrast, in the conventional probe substrate 96 illustrated in FIG. 4, a ring flange 940 is attached to an edge portion of a substrate member 961 using an adhesive (e.g., an acrylic-modified silicone resin adhesive) which is not compatible high temperatures. Therefore, the adhesive may peel off under a high-temperature environment, for example, 150° C. or higher. Furthermore, when the temperature is changed within a range from, for example, a low temperature of −20° C. to a high temperature of 150° C., the adhesive may peel off due to expansion and/or contraction. Thus, if an adhesive that is not compatible with high temperatures is used, the adhesive will not be able to bond sufficiently, causing the substrate member 961 and the ring flange 940 to fall off.

Therefore, in order to prevent the adhesive from peeling off and falling off due to aging degradation or expansion and contraction due to heat, in the conventional probe substrate 96, a ring flange 940 is attached to the edge portion of the substrate member 961, and then, as illustrated in FIG. 4, the ring flange 940 and the substrate member 961 are fixed at multiple points (e.g., three points in FIG. 4) with fixing tools such as screws or vises. For example, the ring flange 940 and the substrate member 961 are provided with threaded holes (hereinafter also referred to as “fixing holes”) 941 in advance at corresponding positions, so as to be fixed by screwing fixing tools such as screws into the threaded holes 941, as illustrated in FIG. 4.

In contrast, since the probe substrate 16 according to the present embodiment uses the high-temperature-compatible bonding material 60, it does not need to be fixed by means of the fixing tools as conventional.

In other words, a conventional probe substrate 96 having a ring flange 940 attached to the edge of the substrate member 961 requires the ring flange 940 and the substrate member 961 to have a plurality of threaded holes 941 for screwing the fixing tools such as screws, and the probe substrate 96 requires that a screw or the like (fixing tool) be screwed into each of the plurality of threaded holes 941.

In contrast, a plurality of threaded holes (fixing hole) is not provided in the ring flange 40 and the substrate member 161 in the probe substrate 16 according to the embodiment. That is, there is none of a plurality of threaded holes 941 in the ring flange 40 and the substrate member 161, and there is no threaded hole (fixing tool) in the probe substrate 16 assembled with the ring flange 40 attached.

Conventionally, processing time is required for providing threaded holes 941 in the substrate member 961 and the ring flange 940 and for screwing the screws into the threaded holes; but according to the present embodiment, processing time required for screw attachment can be eliminated, thereby improving productivity.

Moreover, conventionally, cracks may occur in the ceramic substrate member 961 when forming the threaded holes 941 in the substrate member 961. Moreover, when screwing screws into the threaded holes 941, cracks could occur depending on the fitting state of the screws. However, according to the probe substrate 16 of the present embodiment, since it is not necessary to provide the threaded holes 941, a possibility of cracks can be eliminated.

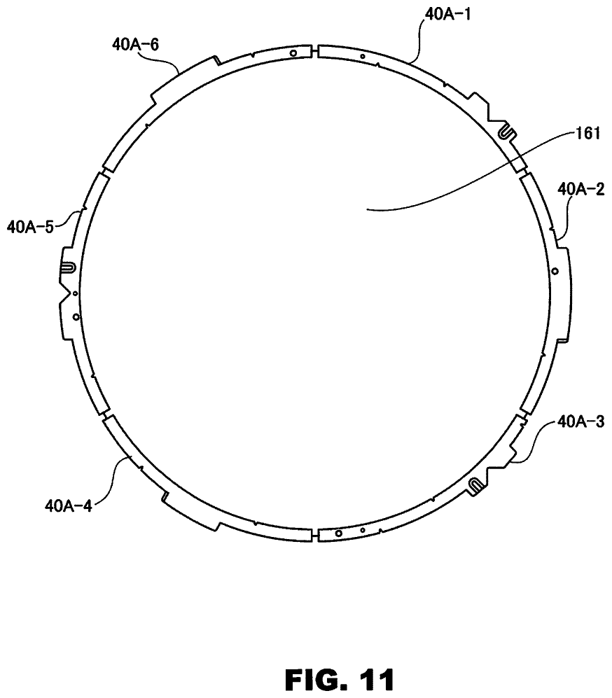

FIGS. 11 to 13 are diagrams illustrating modified examples of the ring flange (annular flange).

Although the ring flange 40 illustrated in FIG. 3B is one-piece structure, the structure of the ring flange 40 is not limited to such an example and may be ring flanges 40A-1 to 40A-6 having a structure divided into six parts, as illustrated in FIGS. 11 to 13. The ring flanges 40A-1 to 40A-6 in FIG. 11 are six parts divided at approximately equal intervals.

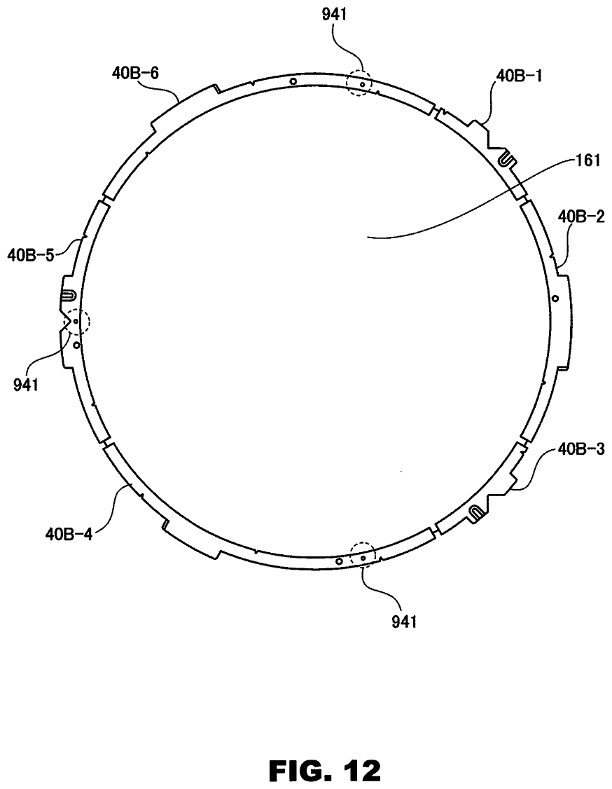

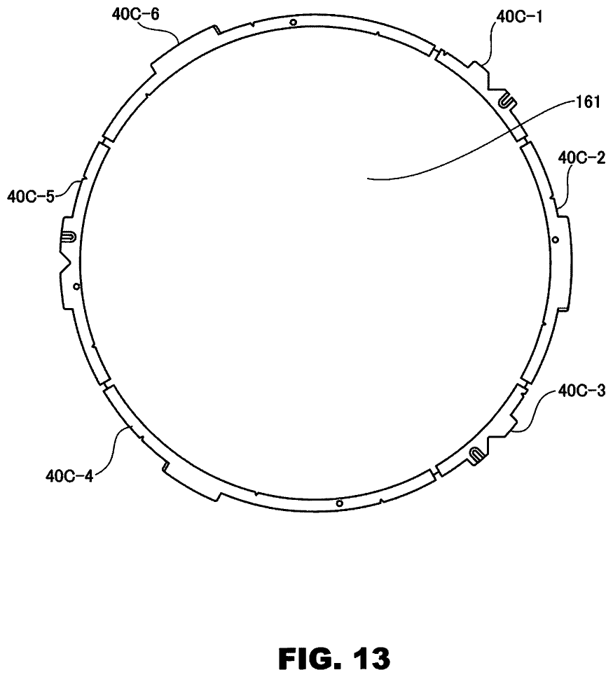

Ring flanges 40B-1 to 40B-6 illustrated in FIG. 12 are six parts divided at arbitrary intervals rather than at equal intervals, and a threaded hole 941 is provided in any of the ring flanges 40B-4, 40B-5, and 40B-6 among the six ring flanges 40B-1 to 40B-6. Ring flanges 40C-1 to 40C-6 illustrated in FIG. 13 are six parts divided at arbitrary intervals rather than at equal intervals, and have no threaded hole.

Conventional ring flanges require fixing with screws or the like, but by using the bonding material 60 as in the present embodiment, fixing tools such as screws are not required. Therefore, as illustrated in FIGS. 11 and 13, the ring flange 40 for assembling the probe substrate 16 may be replaced with the plurality of ring flanges 40A-1 to 40A-6.

For example, as illustrated in FIG. 12, when multiple ring flanges 40B-1 to 40B-6 are used, conventionally it is necessary to provide fixing holes 941 in all members. However, as illustrated in the example of FIG. 12, multiple ring flanges can be designed such that fixing holes 941 are provided only in the necessary members (e.g., ring flanges 40B-4, 40B-5, 40B-6), thereby allowing for variation in the configuration of the ring flange as an assembly part.

In the examples illustrated in FIGS. 11 to 13, the ring flange is divided into six parts, but the number of parts is not limited to such an example.

### (A-3) Detailed Description of Bonding Material 60

Next, the bonding material 60 according to the present embodiment will be described in detail.

The bonding material 60 is capable of improving the bonding strength and relaxing stress even under high-temperature environments of, for example, 150° C. or higher. Moreover, the bonding material 60 is capable of improving the bonding strength and relaxing stress even when temperature changes ranging from a low temperature of −20° C. to a high temperature of 150° C.

Conventionally, when assembling the probe substrate 16, a general-purpose adhesive, which is not compatible with high temperatures, is used for bonding the ceramic substrate member 161 to the stainless steel ring flange 40. On the other hand, in the case of semiconductor integrated circuits mounted in automobiles, smart phones, and the like, it is required to maintain performance according to specifications even under high-temperature environments, and the probe cards used to perform electrical testing of such semiconductor integrated circuits are also required to be compatible with high temperatures.

However, since a general-purpose adhesive used conventionally is not compatible with high temperatures, the adhesive may soften and the bonding strength may decrease, and therefore the substrate member 161 and the ring flange 40 may break. Moreover, since each coefficient of thermal expansion of ceramics and stainless steel are different from each other, a difference in thermal expansion occurs due to temperature changes, large stress may act on the ceramic substrate member 161, and cracks may occur in the substrate member 161.

Therefore, in the present embodiment, the bonding material 60 is used having a high bonding strength even under high-temperature environments and capable of relaxing thermal stress caused by differences in thermal expansion due to temperature changes.

The bonding material 60 contains at least a thermosetting resin and a synthetic rubber. In the present embodiment, the bonding material 60 bonds the substrate member 161, which is a ceramic substrate, and the stainless steel ring flange 40. It is to be noted that, if the bonding material 60 can be used for bonding the ceramic material and the stainless steel, it can also be used for bonding other than bonding the substrate member 161 and the ring flange 40. By bonding the ceramic material and the stainless steel with the bonding material 60, stresses caused by differences in thermal expansion can be relaxed. Therefore, the ceramic material and the stainless steel can be reliably bonded to each other also under high-temperature environments, while reducing a possibility of occurrence of cracks in the substrate member 161.

In order to relax a stress caused by thermal expansion due to temperature changes, it is necessary to reduce an elastic modulus of the bonding material 60, but a bonding material having a low elastic modulus generally has a low bonding strength.

On the other hand, a thermosetting resin can be used as a resin having a high bonding strength, and an epoxy resin is suitable as the thermosetting resin. However, generally, such an epoxy resin has a high bonding strength but has a high elasticity.

Therefore, the present embodiment uses a rubber-modified epoxy resin adhesive obtained by adding a flexible (i.e., low elastic modulus) rubber composition to an epoxy resin. Consequently, it is possible to realize both a low elastic modulus and a high bonding strength.

The bonding material 60 as a rubber-modified epoxy resin adhesive is, for example, a resin composition containing an epoxy resin as a main component, an acrylonitrile-butadiene copolymer having polar groups at both ends, an epoxy resin curing agent, etc.

For example, it is preferable that the bonding material 60 is a mixture of 100 parts by weight of epoxy resin, 10 to 80 parts by weight of acrylonitrile-butadiene copolymer, and 1 to 50 parts by weight of an epoxy resin curing agent. The bonding material 60 has characteristics of a high bonding strength and low elastic modulus under high temperature environments of 150° C. or higher.

Alternatively, the bonding material 60 may also contain inorganic fillers, such as silica, silver, calcium carbonate, and mica. For example, these inorganic fillers may be contained in powder form. However, since the elastic modulus becomes high, the contained amount is preferably 30 parts by weight or less, and more preferably 20 parts by weight or less.

Furthermore, in addition to the above components, the bonding material 60 may contain stress relaxation agents, such as rubber particles, and other low-elasticity resins, rheology control agents, defoaming agents, adhesion promoters, antioxidants, diluents, coloring agents, and the like, as long as the properties are not impaired.

The bonding material 60 is cured when heated to bond the member to each other. If the heat cure temperature is less than 100° C., the adhesive is not cured and sufficient bonding strength cannot be obtained. On the other hand, if the heat cure temperature is 200° C. or higher, the stress occurs due to the difference in linear expansion of the members during post-cure cooling increases, and there is a risk that cracks may occur in the substrate member 161. Therefore, the heat cure temperature is preferably 100° C. to 200° C., and more preferably 125° C. to 150° C.

If the heat cure time is less than 30 minutes, the bonding material 60 is not cured and sufficient bonding strength cannot be obtained. Therefore, the heat cure time is preferably 30 minutes or more, and more preferably 1 hour or more.

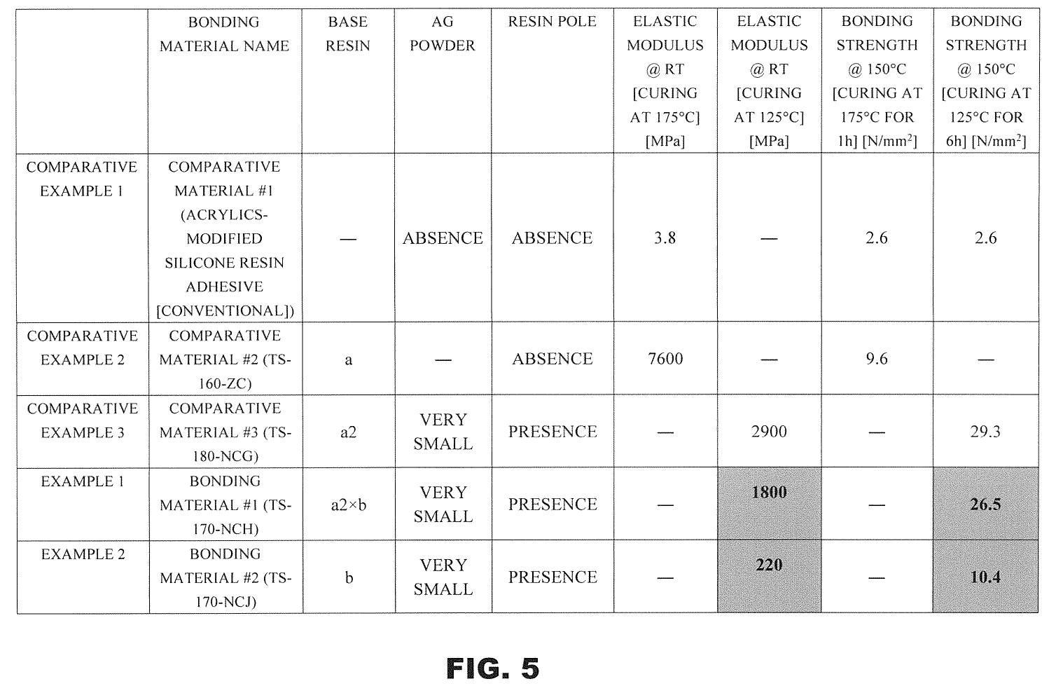

FIG. 5 is a diagram illustrating characteristics of an example of the bonding material 60 according to the embodiment.

In FIG. 5, Examples 1 and 2 are examples of the bonding material 60, and Comparative Examples 1 to 3 are examples for comparison with the characteristics of Examples 1 and 2.

For example, a sample, in which a stainless steel ring flange 40 and a ceramic substrate member 161 are bonded to each other using the bonding material 60, is placed in an environment of 175° C. (or 125° C.) for 1 hour (or 6 hours) to cure the bonding material 60. Moreover, the elastic modulus under an environment of 175° C. (or 125° C.) is measured, and the bonding strength is measured under an environment of 150° C.

Hereinafter, Comparative Examples 1 to 3 are compared with Examples 1 and 2.

The component of comparative material #1 in Comparative Example 1 is a conventional acrylics-modified silicone resin adhesive. The heat cure temperature is room temperature (RT), and the heat cure time is 24 hours. In this case, it can be seen that the bonding strength under a temperature of 150° C. is 2.6 N/mm², which is low bonding strength, and the elastic modulus under room temperature (RT) is 3.8 MPa, which is low elastic modulus.

The component of the comparative material #2 in Comparative Example 2 is an adhesive in which 12 parts by weight of an epoxy resin curing agent are mixed to 100 parts by weight of an epoxy resin, and 484 parts by weight of silver powder (Ag powder) is added. No acrylonitrile-butadiene copolymer is mixed. The heat cure temperature is 175° C., and the heat cure time is 1 hour. In this case, it can be seen that the elastic modulus at room temperature (RT) is 7600 MPa, which is high elastic modulus, but the bonding strength under the temperature of 150° C. is 9.6 N/mm², which is low bonding strength.

The component of the comparative material #3 in Comparative Example 3 is an adhesive in which 9 parts by weight of an epoxy resin curing agent are mixed to 100 parts by weight of an epoxy resin, and 10 parts by weight of silver powder (Ag powder) is added. No acrylonitrile-butadiene copolymer is mixed. The heat cure temperature is 125° C., and the heat cure time is 6 hours. In this case, the bonding strength under the temperature of 150° C. is 29.3 N/mm² and the elastic modulus under room temperature (RT) is 2900 MPa.

The component of the bonding material #1 in Example 1 is based on a rubber-modified epoxy resin adhesive in which 20 parts by weight of acrylonitrile-butadiene copolymer and 9 parts by weight of an epoxy resin curing agent are mixed to 100 parts by weight of an epoxy resin, and 10 parts by weight of silver powder (Ag powder) is added. In Example 1, the heat cure temperature is 125° C., and the heat cure time is 6 hours. In this case, the bonding strength under the temperature of 150° C. is 26.5 N/mm² and the elastic modulus under room temperature (RT) is 1800 MPa. That is, it is verified that bonding having high bonding strength and low elastic modulus is realized.

The component of the bonding material #2 in Example 2 is based on a rubber-modified epoxy resin adhesive in which 100 parts by weight of acrylonitrile-butadiene copolymer and 9 parts by weight of an epoxy resin curing agent are mixed to 100 parts by weight of an epoxy resin, and 20 parts by weight of silver powder (Ag powder) is added. Also in Example 2, the heat cure temperature is 125° C., and the heat cure time is 6 hours. In this case, the bonding strength under the temperature of 150° C. is 10.4 N/mm² and the elastic modulus under room temperature (RT) is 200 MPa. That is, it is verified that bonding having high bonding strength and low elastic modulus is realized.

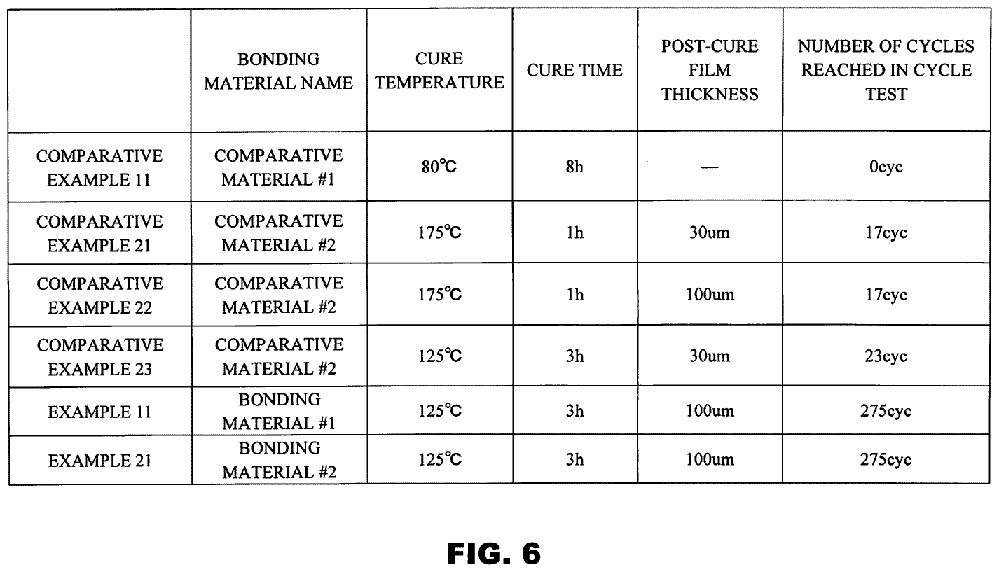

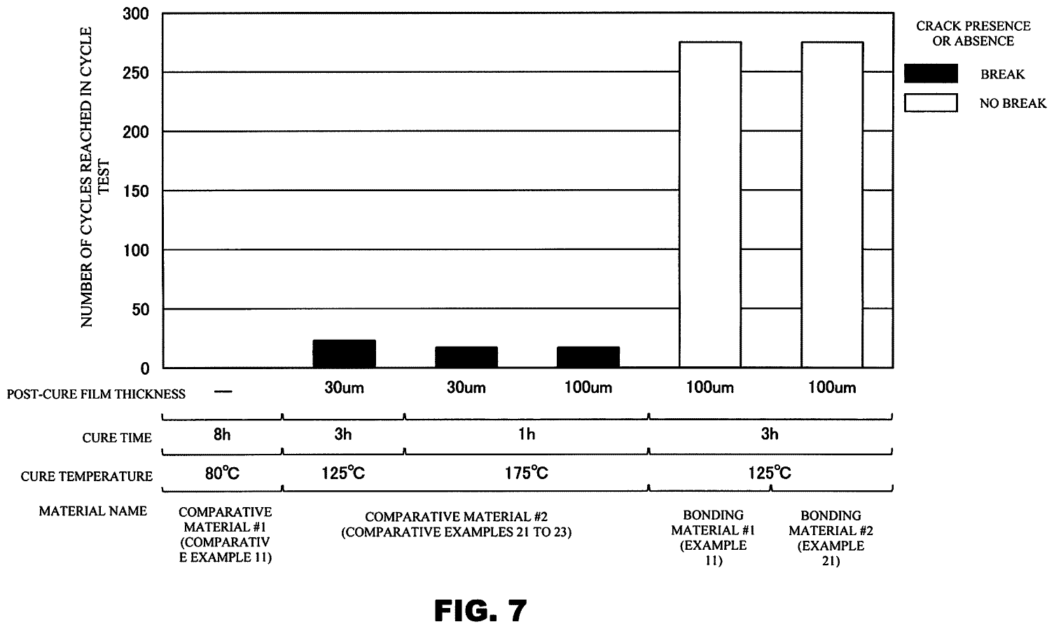

FIGS. 6 and 7 are diagrams illustrating cycle test results when the bonding material 60 according to the embodiment is used.

Here, in order to test durability of the bonding material 60 according to temperature changes, a cycle test is conducted in which the stainless steel ring flange 40 is bonded to the ceramic substrate member 161 by means of the bonding material 60, and the temperature changes between high and low temperatures.

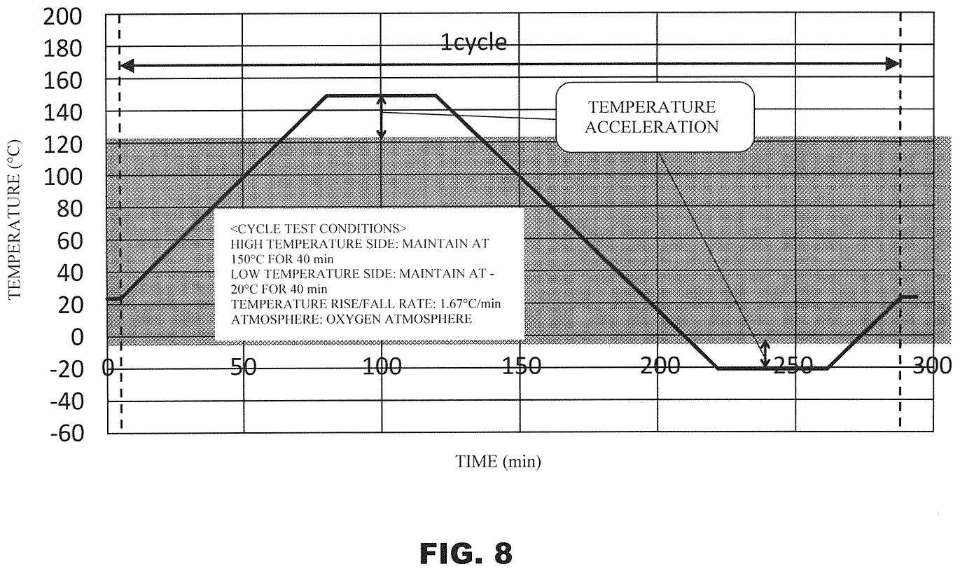

As illustrated in FIG. 8, the conditions of the cycle test are as follows: one cycle (cyc) is from room temperature->high temperature->low temperature->room temperature, in an oxygen atmosphere; the high temperature side is maintained at 150° C. for 40 minutes and the low temperature side is maintained at −20° C. for 40 minutes; and the temperature rise/fall rate is 1.67° C./min.

In Comparative Example 11, the component of the comparative material #1 is used as the bonding material 60. The heat cure temperature is 80° C., and the heat cure time is 8 hours. The comparative material #1 is a conventional adhesive and the number of cycles reached in cycle test is 0 cycle.

In Comparative Example 21, the component of the comparative material #2 is used as the bonding material 60. The heat cure temperature is 175° C. and the heat cure time is 1 hour, and the film thickness after the curing is 30 μm. When the comparative material #2 in Comparative Example 21 is used, the number of cycles reached in cycle test is 17 cycles.

In Comparative Example 22, the component of the comparative material #2 is used as the bonding material 60. The heat cure temperature is 175° C. and the heat cure time is 1 hour, and the film thickness after the curing is 100 μm. When the comparative material #2 in Comparative Example 22 is used, the number of cycles reached in cycle test is 17 cycles.

In Comparative Example 23, the component of the comparative material #2 is used as the bonding material 60. The heat cure temperature is 125° C. and the heat cure time is 3 hours, and the film thickness after the curing is 30 μm. When the comparative material #2 in Comparative Example 23 is used, the number of cycles reached in cycle test is 23 cycles.

In Example 11, the component of the bonding material #1 is used as the bonding material 60. The heat cure temperature is 125° C. and the heat cure time is 3 hours, and the film thickness after the curing is 100 μm. When the bonding material #1 in Embodiment 1 is used, the number of cycles reached in cycle test is 275 cycles.

In Example 21, the component of the bonding material #2 is used as the bonding material 60. The heat cure temperature is 125° C. and the heat cure time is 3 hours, and the film thickness after the curing is 100 μm. When the bonding material #2 in Example 2 is used, the number of cycles reached in cycle test is 275 cycles.

In FIGS. 6 and 7, the number of cycles reached in cycle test for each of the bonding material #1 (Example 11) and the bonding material #2 (Example 21) exceeds a target value (in this case, e.g., 250 cycles), and a favorable result can be obtained. It can be seen that the bonding materials #1 and #2 have lower elastic modulus than that of the comparative material #2 and therefore have advantageous cycle reliability. However, in the case of bonding material #2, there is a seepage of the adhesive component in the ceramic substrate member 61, causing a defective appearance. Therefore, among the bonding materials #1 and #2, the bonding material #1 shows more preferable results.

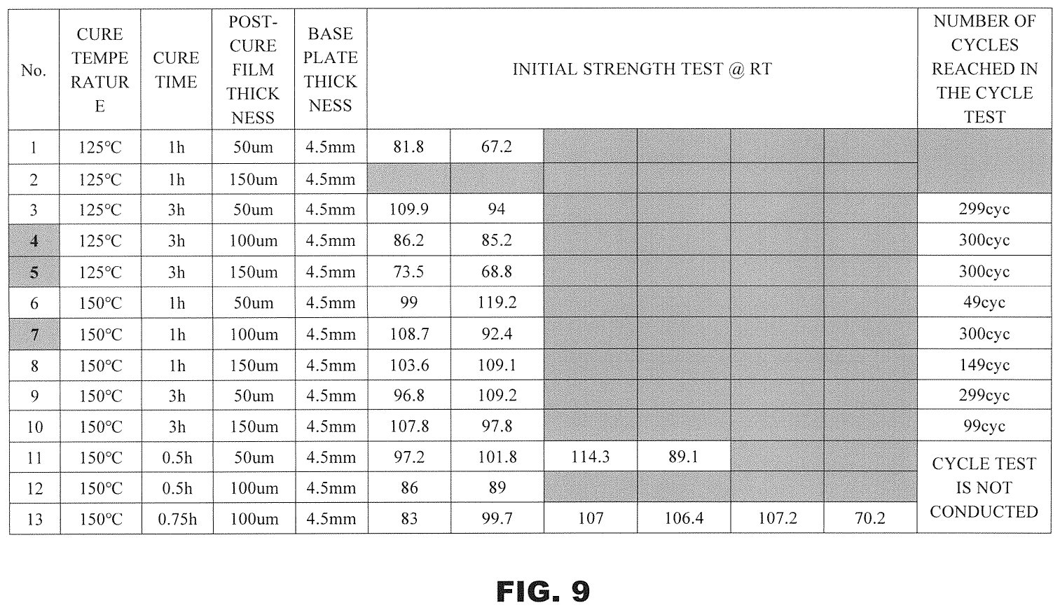

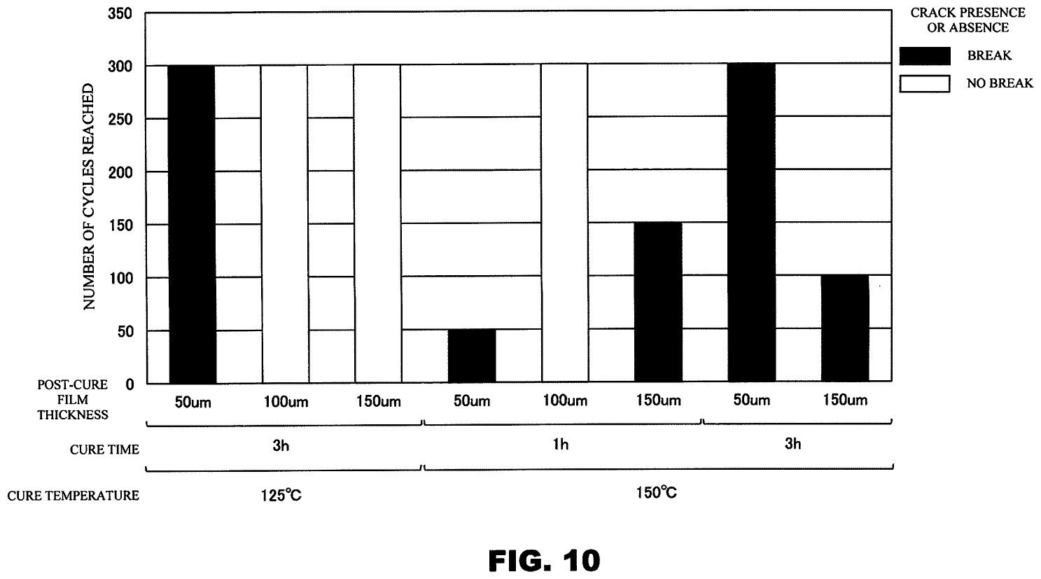

FIGS. 9 and 10 are diagrams illustrating a cycle test result when a cure temperature, cure time, and post-cure film thickness are changed using the bonding material #1 as the bonding material 60 according to the embodiment.

Here, a cycle test is conducted by using the bonding material #1 in which the heat cure temperature, heat cure time, and post-cure film thickness are changed, and a stainless steel material is bonded to the ceramic substrate member 161 having a thickness of 4.5 mm.

As in the above case, as illustrated in FIG. 8, the conditions of the cycle test are as follows: one cycle is from room temperature->high temperature->low temperature->room temperature, in an oxygen atmosphere; the high temperature side is maintained at 150° C. for 40 minutes and the low temperature side is maintained at −20° C. for 40 minutes; and the temperature rise/fall rate is 1.67° C./min.

In FIGS. 9 and 10, when the heat cure temperature is 125° C., among the test cases “No. 1” to “No. 5”, the number of cycles reached in cycle test of each test case “No. 3” to “No. 5”, in which the heat cure time is 3 hours, which is a good result. Furthermore, the test cases “No. 4” and “No. 5” in which the post-cure film thickness is 100 μm to 150 μm shows no break after the cycle test, which is a better result.

Furthermore, when the heat curing temperature is 150° C., among the test cases “No. 6” to “No. 13”, the test case “No. 7”, in which the heat cure time is 1 hour and the post-cure film thickness is 100 μm, shows no break after the cycle test, which is a favorable result.

When the heat cure temperature is 150° C., there is variation in the bonding strength and the state after the cycle test, the heat cure temperature of 125° C. shows better results.

### (A-4) Effects of Embodiment

As described above, according to this embodiment, when bonding the probe substrate and the ring flange attached to the probe substrate, by using a bonding material that has a favorable elastic modulus even under high temperature environments and has a high bonding strength, it is possible to improve the adhesion between the ceramic substrate and the metal ring flange and ensure a reliable bonding therebetween. As a result, it is possible to improve, by applying high loads, the durability of the bonded portion between the probe substrate and the bonded member, thereby extending the life of the bonding therebetween.

### REFERENCE SIGNS LIST

2: Device under test,
2a: Electrode terminal,
3: Wafer chuck,
9: Tester (test apparatus),
10: Electrical connecting apparatus,
12: Support member,
12a: Lower surface of support member,
14: Wiring substrate,
14a: Connecting terminal of wiring substrate,
15: Electrical connecting unit,
16: Probe substrate,
20: Probe,
30: Connector,
40: Ring flange (annular flange),
50: Anchor,
51: Spacer,
60: Bonding material,
121: Through-hole,
141: Through-hole,
151: Flange portion,
161: Substrate member,
162: Multilayer wiring substrate, and
1611: Edge portion.

1. An electrical connecting apparatus configured to electrically contact a probe with each of a plurality of electrode terminals of a device under test to electrically connect a test apparatus to the device under test, the electrical connecting apparatus comprising:
a wiring substrate electrically connected to the test apparatus;
a probe substrate including the plurality of probes; and
a connection unit configured to electrically connect the wiring substrate to each of the plurality of probes of the probe substrate, wherein
an annular flange for connecting the probe substrate to the connection unit is bonded to an edge portion of the probe substrate with a bonding material without using a fixing tool.

2. The electrical connecting apparatus according to claim 1, wherein a fixing hole is not provided in the edge portion of the probe substrate and the annular flange.

3. The electrical connecting apparatus according to claim 1, wherein the edge portion of the probe substrate is a ceramic material, the annular flange is a metallic material, and the bonding material for bonding the annular flange to the edge portion of the probe substrate includes a rubber-modified epoxy resin obtained by adding a rubber composition.

4. The electrical connecting apparatus according to claim 3, wherein the bonding material has a bonding strength of 10 to 30 N/mm² under an environment of 150° C. or higher.

5. The electrical connecting apparatus according to claim 3, wherein the bonding material has a thickness of 100 μm under an environment where a cure temperature is 125° C. and cure time is 1 hour to 3 hours.

6. The electrical connecting apparatus according to claim 1, wherein the annular flange is formed by combining a plurality of component members, and a part of or all of the plurality of component members of the annular flange is bonded to the edge portion of the probe substrate with the bonding material.
